(19) United States
(12) Patent Application Publication
(10) Pub. No.: US 2014/0219764 A1
(43) Pub. Date: Aug. 7, 2014

(54) CENTERING GUIDE FOR WAFERS OF DIFFERENT SIZES

(71) Applicant: SPINTRAC SYSTEMS, INC., Santa Clara, CA (US)

(72) Inventor: Alan W. Kukas, Santa Clara, CA (US)

(73) Assignee: Spintrac Systems, Inc., Santa Clara, CA (US)

(21) Appl. No.: 13/758,782

(22) Filed: Feb. 4, 2013

(51) Int. Cl. H01L 21/68

(52) U.S. Cl. CPC H01L 21/68
USPC 414/751.1; 414/754; 414/816

(57) ABSTRACT

An apparatus for centering workpieces of different sizes, particularly wafers, featuring a single plane centering guide. The guide features a plate having a cutout region with a first arcuate cutout within which a portion of a circumference of a first circular workpiece is nestable and a second arcuate cutout adjacent to and deeper than the first arcuate cutout and centered along the cutout region within which a portion of a circumference of a smaller second circular workpiece is nestable. The arcuate cutouts and nested workpiece have centers of curvature along a common centerline that are collinear with a linear path. The workpiece delivery device horizontally moveable along the linear path, delivers a workpiece to the nesting position thereby centering the workpiece relative to the first or second arcuate cutout. From the centered position, the workpiece delivery device may deliver the workpiece to a predetermined position.

### TECHNICAL FIELD

The invention relates generally to workpiece positioning devices and, more particularly, to devices for positioning workpieces of different sizes.

### BACKGROUND ART

Workpiece positioning devices for positioning semiconductor wafers of a single size and different sizes are known in the art. U.S. Pat. No. 5,044,399 to Sullivan et al. describes a catcher used in positioning an integrated circuit slice of a single size. U.S. Pat. No. 4,024,944 describes a stop having an arcuate bumper that is used to position a wafer of a single size.

A problem associated with devices that position wafers of a single size is that when different diameter wafers are processed, the stops or other equipment for positioning wafers of a particular size must be changed to match with wafers of different diameter thus slowing down wafer processing time. Wafer operations can involve wafer coating, baking, cooling, inspection, photolithography, annealing, and so on. Robotic grippers must pick up wafers, then place them in a desired position. Part of the problem involves centering a wafer with respect to a motion path or track. U.S. Pat. No. 4,315,705 to Flint describes stops used to center a wafer of a single size moving in a linear track.

With regard to positioning devices for wafers of different diameters, U.S. Pat. No. 5,669,752 describes a wafer transferring unit moveable along a path and an elevatable wafer stopping unit having stepped and arc shaped walls of different depths whose center of curvature coincide. U.S. Pat. No. 5,885,054 to Kato et al. describes a stage with a shaft and four supporting arms for supporting wafers of different sizes which is elevatable and rotatable. U.S. Pat. No. 6,530,157 to Henderson et al. describes a device for positioning workpieces of different sizes comprising ring bars pivotable on one end and whose distal end has a circular shape that may increase or decrease in diameter as the bars are pivoted to center workpieces of different sizes.

Though these devices position wafers of multiple sizes, what is desired is a simpler, less complicated device for positioning and centering wafers of different sizes.

### SUMMARY OF THE INVENTION

The invention comprises a centering guide for different sized wafers being handled by a workpiece delivery device such as a robotic end effector, or a wafer gripper, or by sliding along a track. The centering guide features a planar plate with an edge for receiving and stopping a peripheral edge of a workpiece, for example a wafer, moving on a linear path of the workpiece delivery device. The edge receives circular wafers having different diameters and so a single centering guide can be used with a linear track without the need to change configurations when wafers having different diameter are processed. The edge of the centering guide plate defines a cutout region with a first arcuate cutout and a second smaller arcuate cutout disposed deeper than the first arcuate cutout. A portion of a first workpiece circumference is nestable within the first arcuate cutout and a portion of a circumference of a second smaller workpiece is nestable within the second arcuate cutout. Each nested workpiece is centered relative to its corresponding cutout. The two cutouts and nested workpiece share a common centerline that is collinear with the linear path.

The workpiece delivery device delivers a wafer to the centering guide along the linear path, pushing the wafer into the centering guide. One of the cutouts receives the wafer and stops further motion of the workpiece delivery device. The size of the wafer is sensed, for example, from its cassette or by optical means, and the workpiece delivery device is moved to a first predetermined position dependent on the particular wafer size. The workpiece delivery device is positioned at the first predetermined position near the centering guide and the workpiece delivery device delivers the centered workpiece to a second predetermined position, for example, at a processing station that is disposed along the linear path. The processing station has, for example, an axis perpendicular to the processing path with a center which has a centerline collinear with the centerline of the first and second cutouts and centered workpiece so that when the workpiece delivery device delivers the workpiece from the first predetermined position at the centering guide to the second predetermined position, for example, at the workpiece processing center, the workpiece is positioned at a desired position, for example, a centered position relative to the workpiece processing station.

### BRIEF DESCRIPTION OF THE DRAWINGS

FIG. 1 is a top view of an apparatus of the present invention.

FIG. 2 is a top view of a centering guide of the present invention.

FIG. 3 is a top view of another centering guide of the present invention.

FIG. 4 is a top sectional view of the centering guide of FIG. 2 taken along curve A.

FIG. 5 is a top view of the centering guide of FIG. 2 with wafers.

FIG. 6 is a top view of the centering guide of FIG. 3 with wafers.

FIG. 7 is a top sectional view of the centering guide of FIG. 3 taken along curve B.

### DETAILED DESCRIPTION OF THE INVENTION

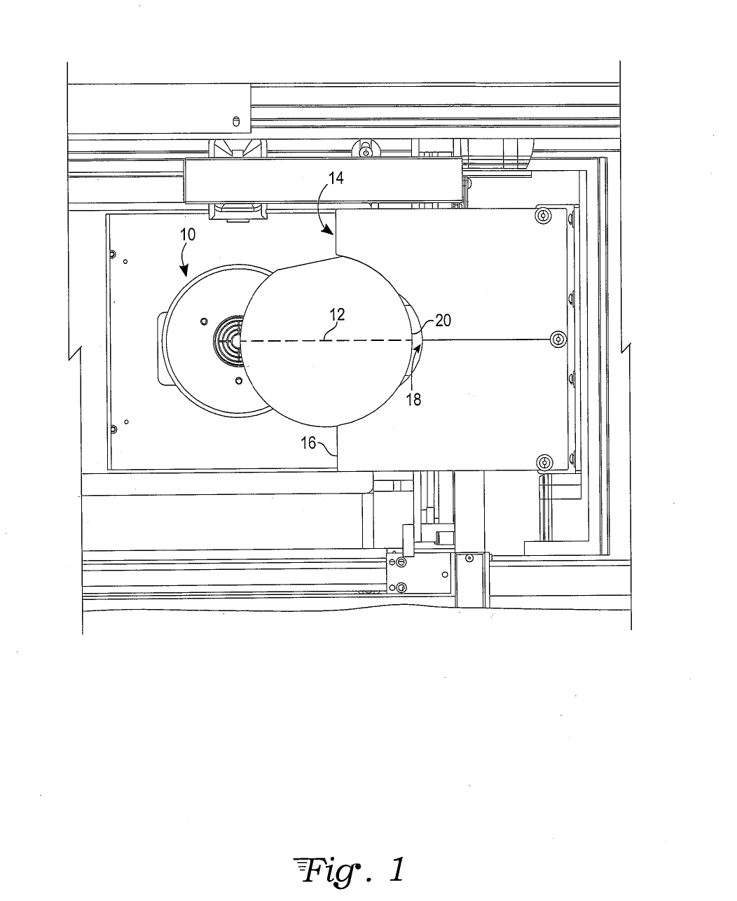

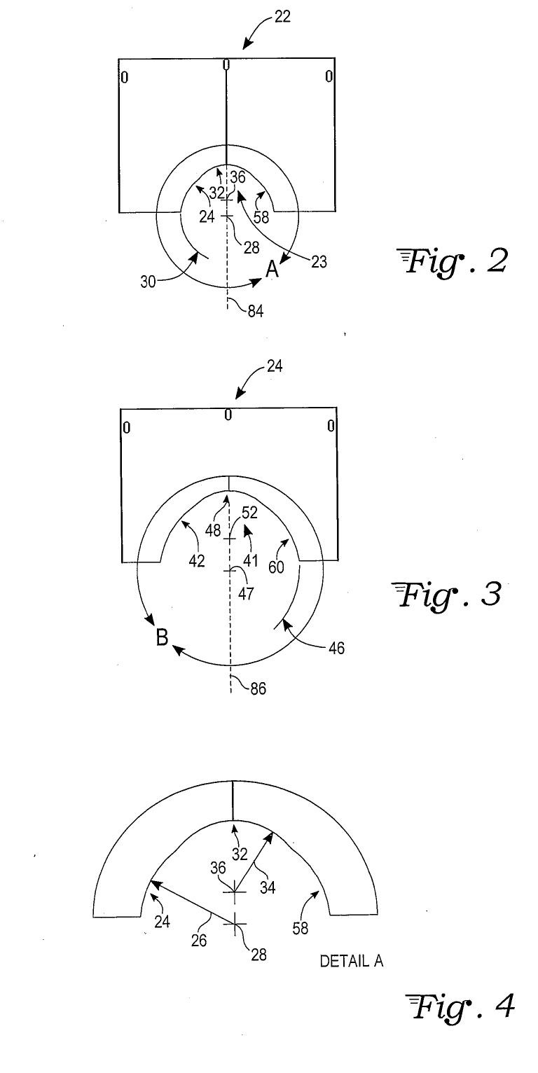

As shown in FIG. 1, the apparatus of the present invention is seen featuring a workpiece delivery device 10 horizontally moveable along a linear path 12 or track and a centering guide 14 disposed on the linear path receiving a workpiece delivered by the workpiece delivery device. Centering guide 14 of the present invention includes a guide plate 16 having a cutout region 18 with an edge defining arcuate cutouts for receiving and stopping a peripheral edge of a workpiece 20, for example a wafer, moving with the wafer delivery device on the linear path towards the centering guide 14. The centering guide cutout region has a first arcuate cutout and a second deeper and smaller arcuate cutout (seen in FIGS. 2 and 3) receiving and centering circular wafers having different diameters so a single centering guide can be used with the linear path 12 without the need to change configurations when wafers with different diameters are processed.

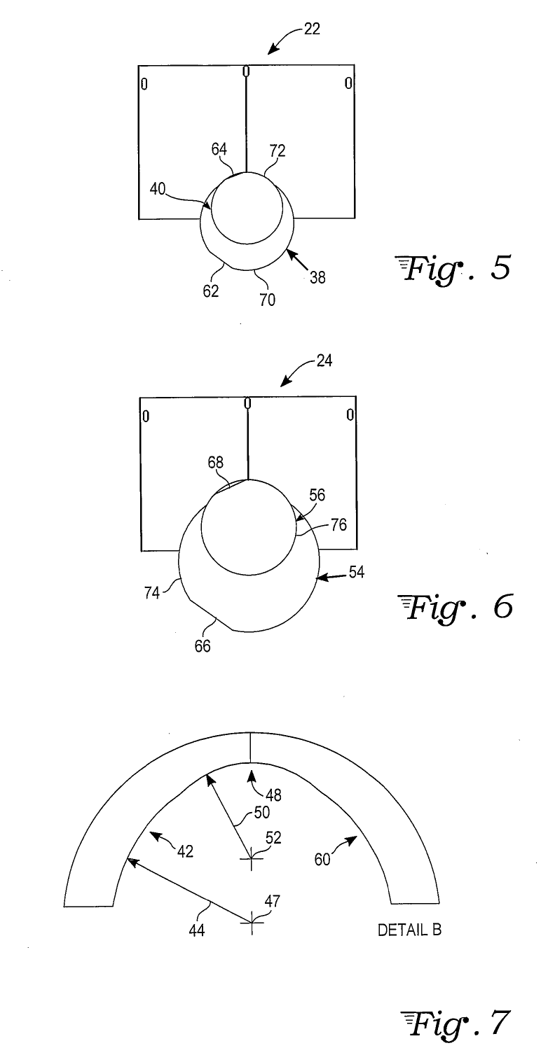

As shown in FIGS. 2-7, centering guides are of different select dimensions to receive workpieces of different sizes. For example, as shown in FIGS. 2, 4, and 5, centering guide 22 includes a cutout region 23 with a first arcuate cutout 24 having a radius 26 measured from its edge to its center of curvature 28 of, for example, 1.97 inches (50 mm) and a diameter of 3.94 inches (100 mm) measured across a circle formed by curvature 30 extended into the circle. Centering guide 22 includes a second arcuate cutout 32 centered along the periphery of the cutout region 23 disposed deeper than the first arcuate cutout 24 and having a smaller radius 34 of, for example, 1.50 inches (38.10 mm) (and a diameter of 3 inches (76.20 mm)) measured from its edge to its center of curvature 36. The cutouts are sized to receive workpieces 38, 40 of matching sizes, as shown in FIG. 5. In this example, first arcuate cutout 24 receives a 3.94 inch (100 mm) diameter wafer 38 and second arcuate cutout 32 receives a 3.00 inch (76.20 mm) diameter wafer 40. Typically, only one workpiece is received at a time, although two are shown as being received.

In another example as shown in FIGS. 3, 6 and 7, the centering guide 24 includes a cutout region 41 with a first arcuate cutout 42 having a radius 44 measured from its edge to its center of curvature 47 of, for example, 2.95 inches (75.03 mm) and a diameter of 5.91 inches (150.06 mm) measured across a circle formed by curvature 46 extended into the circle. Centering guide 24 includes a second arcuate cutout 48 centered along the periphery of the cutout region disposed deeper than the first arcuate cutout 42 and having a smaller radius 50 of, for example, 1.97 inches (50 mm) (and a diameter of 3.94 inches (100 mm)) measured from its edge to its center of curvature 52. The cutouts 42 and 48 are sized to receive workpieces 54, 56 of matching sizes, as shown in FIG. 6. In this example, first arcuate cutout 42 receives a 5.91 inch (150 mm) diameter wafer 54 and second arcuate cutout 48 receives a 3.94 inch (100 mm) diameter wafer 56. Typically, only one workpiece is received at a time although two are shown as being received.

In one embodiment a third arcuate cutout which mirrors the first arcuate cutout is present. As shown in FIGS. 2 and 4, third arcuate cutout 58 is disposed adjacent to the second arcuate cutout 32 and has the same radius, diameter and depth as the first arcuate cutout 24. As shown in FIGS. 3 and 6, third arcuate cutout 60 is disposed adjacent to the second arcuate cutout 48 and has the same radius, diameter and depth as the first arcuate cutout 42. Typically, a wafer that is received in first arcuate cutout 24 is also received in third arcuate cutout 58, if present, and a wafer that is received in first arcuate cutout 42 is also received in third arcuate cutout 60, if present. Flat portions, for example 62, 64, 66, 68 or curved portions, for example, 70, 72, 74, 76 of the respective wafers may be received at or nested within the arcuate cutouts to center the wafers. Cutouts 24 and 58 have a center of curvature 28 that is disposed on a centerline 84 collinear with the linear path 12 of the wafer delivery device. Cutout 32 has a center of curvature 36 that is disposed on centerline 84 collinear with the linear path 12 of the wafer delivery device 10. Cutouts 42 and 41 have a center of curvature 47 that is disposed on a centerline 86 collinear with the linear path 12 of the wafer delivery device. Cutout 48 has a center of curvature 52 that is disposed on centerline 86 that is collinear with the linear path 12 of the wafer delivery device 10. Thus, centerline 84 is collinear with centerline 86.

Referring back to FIG. 1, in operation the workpiece delivery device 10, for example a robotic end effector, delivers workpiece 20 from a workpiece supply, such as a cassette (not shown) and from a position along the linear path 12 to the centering guide 14 where the workpiece, for example a wafer, is pushed into the cutout region 18 of the centering guide 14. The robotic end effector is or includes, for example, a vacuum chuck. The robotic end effector may be “U” shaped, circular shaped or another shape and may include means by which a workpiece may be secured to it including a vacuum which may be disposed on a surface (for example, a top surface) of the workpiece delivery device 10. The workpiece delivery device with the workpiece secured thereto moves horizontally along the linear path 12 in a first direction, towards the centering guide 14. As the workpiece delivery device 10 nears the centering guide its speed typically decreases and its vacuum or other securing means is turned off. The workpiece delivery device pushes the workpiece into the centering guide 14 with its linear movement until the workpiece registers with the centering guide (i.e., is received by or nested within the centering guide) without removing, or at least without completely removing, the workpiece from the workpiece delivery device. The workpiece delivery device stops moving when the workpiece registers with the centering guide. A portion of the circumference of the workpiece nests with or is received by the corresponding arcuate portion, either one of the first arcuate cutouts 24, 42, (FIGS. 2 and 3), one of the second arcuate cutouts 32, 48 (FIGS. 2 and 3), or one of the first and one of the third arcuate cutouts 58, 60 (FIGS. 2 and 3) thus centering the workpiece relative to the corresponding cutout(s) of centering guide 22 or 24.

The size of the workpiece is sensed, for example by its cassette or by optical means (not shown), and the workpiece delivery device 10 is positioned at a predetermined position dependent upon the sensed workpiece size. For example, if the workpiece is sensed to be a first size, the workpiece delivery device is positioned at a first predetermined position and if the workpiece is sensed to be a second size, the workpiece delivery device is positioned in a different predetermined position. In one example, the predetermined position is one where the centered workpiece is centered on the workpiece delivery device 10.

At the predetermined position at the centering guide, the centered workpiece is re-secured, for example by vacuum means, and the workpiece delivery device moves horizontally along the linear path 12 in, for example, the opposite direction with the re-secured workpiece towards the second predetermined location, for example, a workpiece processing station (not shown). Workpiece processing station is, for example, a spin-spray processing system having a spin chuck with an axis perpendicular to the linear path 12 and a center which has a centerline collinear with the centerline of the arcuate cutouts, centered workpiece and linear path 12. At the second predetermined position workpiece delivery device 10 releases the secured workpiece to a desired location which, in one example, is a centered position at the workpiece processing station chuck. The workpiece delivery device may additionally move up and down in a direction perpendicular to the linear path when delivering the workpiece. For example, in FIG. 1, the workpiece delivery device moves horizontally from the predetermined position at the centering guide to a second predetermined position which is, for example, less elevated than the centering guide, where it moves down vertically to release and deliver the workpiece to the second predetermined position.

What is claimed is:

1. An apparatus for centering circular workpieces of different sizes received along a linear path, comprising:
a plate having a cutout region with a first arcuate cutout within which a portion of a circumference of a first circular workpiece is nestable and a second arcuate cutout adjacent to the first arcuate cutout and centered along the cutout region, said second arcuate cutout disposed deeper than said first arcuate cutout and within which a portion of a circumference of a smaller second circular workpiece is nestable, wherein the first and second arcuate cutouts have centers of curvature along a common centerline that is collinear with the linear path, and wherein said linear path delivers the workpiece to a nesting position with either the first or second arcuate cutouts thereby centering the workpiece relative to the first or second arcuate cutout.

2. The apparatus of claim 1, wherein the cutout region further comprises a third arcuate cutout disposed adjacent to the second arcuate cutout, said third arcuate cutout having a depth equal to a depth of said first arcuate cutout and within which a portion of the circumference of the first circular workpiece is nestable.

3. The apparatus of claim 1, wherein the workpiece is a semiconductor wafer.

4. The apparatus of claim 1, wherein a radius of the first arcuate cutout measured from an edge of the first arcuate cutout to its center of curvature is larger than a radius of the second arcuate cutout measured from an edge of the second arcuate cutout to its center of curvature.

5. The apparatus of claim 1, wherein the plate is planar.

6. A system for centering circular wafers of different sizes, comprising:
a wafer gripper horizontally moveable along a linear path; and
a centering guide comprising a plate having a first cutout region with a first arcuate cutout region with a radius measured from its edge to its center of curvature, said first arcuate cutout radius concentric with a wafer of a radius receivable by said first arcuate cutout region and a second arcuate cutout region adjacent to and deeper than the first arcuate cutout region and centered along the first cutout region with a second radius measured from its edge to its center of curvature smaller than said first arcuate cutout radius, said second arcuate cutout radius concentric with a second smaller wafer receivable by the second arcuate cutout region, wherein the first and second arcuate cutout radii have centers along a common centerline that is collinear with the linear path.

7. The system of claim 6, wherein the cutout region further comprises a third arcuate cutout region disposed adjacent to the second arcuate cutout region, said third arcuate region with a third radius centered along the cutout region with the third radius measured from its edge to its center of curvature that is longer than said second arcuate cutout radius, said third arcuate cutout radius, being concentric with the first wafer.

8. The system of claim 6, wherein the wafer gripper is movable from a predetermined position at the centering guide at which the wafer was received by one of the arcuate cutout regions to a second predetermined position.

9. A method for centering workpieces of different sizes, comprising:
providing a workpiece delivery device moveable along a linear path;
providing a centering guide comprising a plate having a cutout region with first and second arcuate cutouts, the second arcuate cutout adjacent to the first arcuate cutout and centered along the cutout region, the second arcuate cutout disposed deeper than the first arcuate cutout, wherein the first and second arcuate cutouts have centers of curvature along a common centerline that is collinear with the linear path of the workpiece delivery device;
securing a workpiece to the workpiece delivery device; and
horizontally moving the workpiece delivery device and secured workpiece along the linear path toward the centering guide until the workpiece contacts the centering guide and a portion of the circumference of the workpiece nests within either the first or second arcuate cutout thereby centering the workpiece relative to the first or second cutout.

10. The method of claim 9, wherein securing the workpiece to the workpiece delivery device comprises securing the workpiece on a top surface of the workpiece delivery device with a vacuum.

11. The method of claim 10, further comprising releasing the secured workpiece from the vacuum of the workpiece delivery device as the workpiece delivery device approaches the centering guide without removing the workpiece from the top surface of the workpiece delivery device.

12. The method of claim 11, further comprising re-securing the workpiece to the workpiece delivery device with the vacuum after the workpiece nests within either the first or second arcuate cutout.

13. The method of claim 9, further comprising decreasing the speed at which the workpiece delivery device moves as the workpiece delivery device nears the centering guide.

14. The method of claim 9, further comprising sensing the size of the workpiece and, after a portion of the circumference of the wafer nests, positioning the workpiece delivery device at a first predetermined position if the workpiece is a first size and positioning the workpiece delivery device at a second predetermined position if the workpiece is a second size.

15. The method of claim 12, further comprising positioning the workpiece delivery device at a first predetermined position at the centering guide when the workpiece nests within the first arcuate cutout and positioning the workpiece delivery device at a second predetermined position at the centering guide when the workpiece nests within the second arcuate cutout.

16. The method of claim 15, further comprising moving the workpiece delivery device and workpiece re-secured thereto to a third predetermined position and releasing the re-secured workpiece from the workpiece delivery device at a centered position at the third predetermined position.

17. The method of claim 9, wherein the workpiece delivery device includes a vacuum chuck.
